(19) United States
(12) Patent Application Publication
(10) Pub. No.: US 2025/0271480 A1
(43) Pub. Date: Aug. 28, 2025

(54) PROBE ASSEMBLY FOR CALIBRATING RF POWER SIGNALS TO A DEVICE PIN

(71) Applicant: Advantest Corporation, Tokyo (JP)

(72) Inventors: Stephen Scott Moore, Portland, OR (US); Daniel Stephen Lam, San Jose, CA (US)

(21) Appl. No.: 18/674,142

(22) Filed: May 24, 2024

Related U.S. Application Data
(60) Provisional application No. 63/557,117, filed on Feb. 23, 2024.

(51) Int. Cl. G01R 29/08; G01R 35/00

(52) U.S. Cl. CPC G01R 29/0878; G01R 35/005

(57) ABSTRACT

Various embodiments disclosed herein provide a method for calibrating power signals received at one or more device socket pins associated with a plurality of sockets in a multi-site calibration assembly. The method comprises inserting a calibration probe assembly into a test socket, programming a test equipment communicatively coupled to the test socket to control operation of a first switch to selectively couple a first pin of the test socket to a first equipment port of the test equipment, and control operation of a second switch to selectively couple a second pin of the test socket to a second equipment port of the test equipment, electrically stimulating the first pin with an RF signal via the first equipment port, measuring the RF signal propagated from the first pin and received at the second pin via the second equipment port, and determining a power value associated with the RF signal.

### CROSS-REFERENCE TO RELATED APPLICATIONS

This application claims priority and benefit of provisional patent application Ser. No. 63/557,117 Attorney Docket Number ATSY-0140-00.00US, with filing date 02/23/2024, which is hereby incorporated by reference in its entirety.

### BACKGROUND

### Field of the Various Embodiments

The various embodiments pertain broadly to the field of power measurement for devices under testing (DUTs), and more specifically to an apparatus designed for calibration to enhance the accuracy of power measurements received by a DUT.

### Description of the Related Art

A device under test (DUT) is typically tested to determine the performance and consistency of the device before the device is sold. For example, a DUT can be tested using a large variety of test cases, and the result of the test cases can be compared to an expected output result. When the result of a test case does not match a satisfactory value or range of values, the device can be considered a failed device or outlier, and the device can be binned based on performance parameters, etc.

A DUT is usually tested by test equipment (e.g., automatic or automated test equipment (ATE)), which may be used to conduct complex testing using software and automation to improve the efficiency of testing. The DUT may be any type of semiconductor device, wafer, or component that is intended to be integrated into a final product, such as a computer, network interface, memory, or other hardware component, such as a solid-state drive (SSD). By removing defective or unsatisfactory chips at manufacture using ATE, the quality of the yield can be significantly improved.

The DUT is typically placed inside a socket for purposes of testing. FIG. 1 illustrates a generalized assembly for testing devices. The assembly 100 shown in FIG. 1 is commonly utilized with test equipment (e.g., ATE 106). In this setup, a DUT 102 is placed into a test socket 101, enabling electrical connectivity to the device socket pins 103 via the device solder balls 104. Generalized tester systems are often calibrated up to the tester pogo pins 105. In other words, generalized systems are able to characterize and calibrate the signal pathway leading up to the tester pogo pins 105, but no further. However, typical tester systems do not calibrate or characterize the signal path through the loadboard 108 to the device socket pins 103. The socket sp2 files, which attempt to model signal loss through a socket, provided by socket vendors are not correct or accurate enough to determine the precise RF power being delivered to the socket pins 103. Accordingly, test engineers often face the challenge of not knowing precisely the actual signal power, often radio frequency (RF), that is being transmitted to each DUT pin (e.g., solder balls 104). This uncertainty is due to the losses associated with the loadboard PCB trace and the socket.

Some approaches to DUT testing using external equipment involve using a probe assembly that allows the external equipment to be communicatively coupled to a DUT pin for device/bench testing. However, these approaches typically are designed to allow a signal generating device (e.g., an RF signal generator) or a signal measurement device (e.g., a signal analyzer) to be connected to a single device socket pin at a time. Moreover, it is not technically feasible to provide a loopback path that can route a signal from one pin of a DUT to another pin of the same DUT for internal testing by the DUT using existing probe assembly approaches. This is especially important when testing devices that include internal testing functionality (self-testing), such as the ability to generate a signal, re-route, and receive the signal back (loopback). These types of DUTs are typically devices that include multiple antennas, where one antenna can receive a signal transmitted by another antenna of the device. The signal received by the device (and also generated by the device) can be analyzed for device testing purposes or to characterize a signal path or components of the DUT, for example.

An approach that enables testing of different socket pins using external equipment and/or that allows testing of a loopback path for self-testing devices without having to manually connect/disconnect components is desired.

### SUMMARY

Embodiments of the present invention introduce an in-socket calibration probe assembly, designed for seamless integration directly into a device socket. The calibration probe assembly facilitates the direct probing of one or more socket pins via controllable switches, enabling the precise measurement of the actual radio frequency (RF) power being delivered to a device under test (DUT) positioned within the socket utilizing high precision instrumentation. This approach significantly enhances the accuracy of power measurement, as will be elaborated upon further. The actual power supplied to one or more socket pins, and consequently, to the DUT connected via these pins, can be accurately determined during device/bench testing. This precise measurement of power delivery to the DUT is vital for ensuring the integrity and reliability of the testing process, offering a significant improvement over traditional methods that may not provide sufficient accuracy due to losses in the loadboard PCB trace and socket.

According to one embodiment, a method is disclosed, including inserting a calibration probe assembly into a test socket, programming a test equipment communicatively coupled to the test socket to control operation of a first switch to selectively couple a first pin of the test socket to a first equipment port of the test equipment, and control operation of a second switch to selectively couple a second pin of the test socket to a second equipment port of the test equipment, electrically stimulating the first pin with an RF signal via the first equipment port, measuring the RF signal propagated from the first pin and received at the second pin via the second equipment port, and determining a power value associated with the RF signal.

According to some embodiments, determining the power value comprises applying de-embedding factors to the RF signal measured by the measuring.

According to some embodiments, the method includes measuring the de-embedding factors by mounting a calibration probe assembly shorting structure to a bottom of the calibration probe assembly and measuring the de-embedding factors using a vector network analyzer connected to the calibration probe assembly.

According to some embodiments, the calibration probe assembly comprises one or more coaxial cables, wherein the RF signal is propagated through the calibration probe assembly using at least one cable of the one or more coaxial cables, and wherein the measuring the RF signal comprises using external equipment to measure the RF signal that is propagated through the calibration probe assembly.

According to some embodiments, the first equipment port comprises a coaxial connector coupled to a power meter.

According to some embodiments, the method includes testing a device under test (DUT) disposed in the test socket according to the power value associated with the RF signal.

According to another embodiment, a method is disclosed including inserting a plurality of calibration probe assemblies into a respective plurality of test sockets of a multi-site calibration probe assembly, for a first test socket of the plurality of test sockets, programming a test equipment communicatively coupled to the first test socket to selectively couple a first pin of the first test socket to a second pin of the first test socket via a plurality of switches, electrically stimulating the first pin with an RF signal, measuring the RF signal propagated from the first pin to the second pin, and determining a power value associated with the RF signal measured by the measuring.

According to some embodiments, determining the power value comprises applying de-embedding factors to the RF signal measured by the measuring.

According to some embodiments, the method includes programming the test equipment to selectively couple the first pin of the first test socket to a first equipment port of the test equipment and to selectively couple the second pin of the first test socket to a second equipment port of the test equipment.

According to some embodiments, the electrically stimulating the first pin with the RF signal is performed via the first equipment port, and wherein the measuring the RF signal propagated from the first pin to the second pin is performed via the second equipment port.

According to some embodiments, the first equipment port is coupled to an RF signal generator, and wherein the second equipment port is coupled to a power meter.

According to some embodiments, the plurality of test sockets are disposed on a loadboard assembly, the plurality of test sockets are operable to receive devices under test (DUTs), and the loadboard assembly comprises a plurality of switches that selectively couple any of the plurality of test sockets to either components of DUTs disposed in the plurality of sockets, or loopback components of the DUTs, and the DUTs are operable to both generate the RF signal and receive the RF signal via the loopback components.

According to some embodiments, the method includes testing a DUT disposed in the test socket according to the power value.

According to some embodiments, the DUT comprises a first component operable to transmit the RF signal at the first pin and a second component operable to receive the RF signal at the second pin via a loopback path provided by the plurality of switches.

According to different embodiment, a device is disclosed including a test socket comprising a plurality of pins operable to be coupled to pins of a device under test (DUT), a probe assembly comprising a first equipment port and a second equipment port, a plurality of switches operable to selectively couple the plurality of pins of the test socket to one of the first equipment port and the second equipment port, a first bench equipment coupled to the first equipment port and operable to electrically stimulate a first pin of the plurality of pins of the test socket with an RF signal, a second bench equipment coupled to the second equipment port and operable to measure the RF signal propagated from the first pin and received at a second pin of the plurality of pins of the test socket via the second equipment port, and test equipment operable to determine a power value associated with the RF signal.

According to some embodiments, the test equipment is further operable to test the DUT according to the power value when the DUT is disposed in the test socket.

According to some embodiments, the first equipment port is coupled to an RF signal generator and the second equipment port is coupled to a power meter.

According to some embodiments, the plurality of switches are further operable to provide a loopback path between a first pin of the plurality of pins of the test socket and a second pin of the plurality of pins of the test socket.

According to some embodiments, the DUT is disposed in the test socket, and wherein the DUT is operable to generate an RF signal on the loopback path.

According to some embodiments, the DUT is further operable to receive the RF signal from the loopback path, and the loopback path is operable to route the RF signal from the DUT back to the DUT via the plurality of switches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a generalized assembly for testing devices;

FIG. 2A illustrates an in-socket calibration probe assembly, according to one or more aspects of the various embodiments of the present invention;

FIG. 2B illustrates another implementation of the in-socket calibration probe assembly, according to one or more aspects of the various embodiments of the present invention;

FIG. 3 illustrates a cross-section of the in-socket calibration probe assembly, according to one or more aspects of the various embodiments of the present invention;

FIG. 4 illustrates the in-socket calibration probe assembly shown in FIG. 2A mounted on a device test socket, according to one or more aspects of the various embodiments of the present invention;

FIG. 5 illustrates another implementation of the in-socket calibration probe assembly, according to one or more aspects of the various embodiments of the present invention;

FIG. 6A illustrates the manner in which socket pins can be calibrated using a MUX PCB to selectively couple external equipment to the probe assembly, according to one or more aspects of the various embodiments of the present invention;

FIG. 6B illustrates a MUX PCB including multiple switches for selectively coupling external equipment to a probe assembly, according to one or more aspects of the various embodiments of the present invention;

FIG. 6C illustrates a MUX PCB including multiple switches in a loopback configuration, according to one or more aspects of the various embodiments of the present invention;

FIG. 7 illustrates the manner in which the in-socket calibration probe assembly is de-embedded for RF insertion loss, according to one or more aspects of the various embodiments of the present invention;

FIG. 8 illustrates a multi-calibration probe assembly including a switch matrix to selectively couple external equipment to in-socket calibration probe assemblies, according to one or more aspects of the various embodiments of the present invention;

FIG. 9 illustrates the manner in which the multi-calibration probe assembly of FIG. 8 is used to perform calibration, according to one or more aspects of the various embodiments of the present invention;

FIG. 10 illustrates a flow diagram of method steps for calibrating RF power signals to a device pin, according to one or more aspects of the various embodiments of the present invention;

FIG. 11 illustrates an exemplary socket calibration probe assembly that can provide additional calibration capability using a loopback path that couples two pins of the same DUT, according to one or more aspects of the various embodiments of the present invention.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

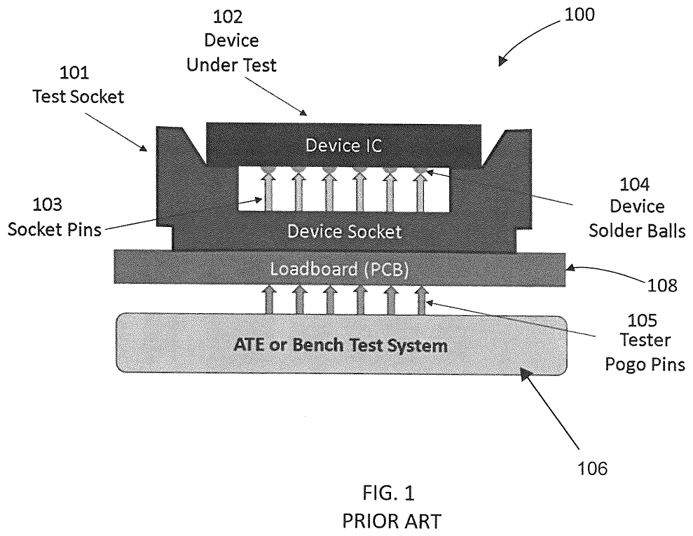

As discussed above in connection with FIG. 1, generalized tester systems are often calibrated up to the tester pogo pins 105. In other words, generalized systems are able to characterize and calibrate the signal pathway leading up to the tester pogo pins 105, but no further. However, typical tester systems do not calibrate or characterize the signal path through the loadboard 108 to the device socket pins 103. Accordingly, test engineers often face the challenge of not knowing precisely the actual signal power, often radio frequency (RF), that is being transmitted to each DUT pin (e.g., solder balls 104). This uncertainty is due to the losses associated with the loadboard PCB trace and the socket.

The disclosed embodiments of the present invention introduce an in-socket calibration probe assembly, designed for seamless integration directly into a device socket. The calibration probe assembly facilitates the direct probing of one or more socket pins, enabling the precise measurement of the actual radio frequency (RF) power being delivered to a device under test (DUT) positioned within the socket utilizing high precision instrumentation. This approach significantly enhances the accuracy of power measurement, as will be elaborated upon further.

A primary technical advantage of these techniques is the capability to accurately ascertain the actual power supplied to one or more socket pins, and consequently, to the DUT connected via these pins, during device/bench testing. This precise measurement of power delivery to the DUT is vital for ensuring the integrity and reliability of the testing process, offering a significant improvement over traditional methods that may not provide sufficient accuracy due to losses in the loadboard PCB trace and socket. By directly measuring at the point of contact with the DUT, this method effectively mitigates potential inaccuracies, leading to more reliable and consistent test outcomes. The device testing can be performed by any suitable test system or equipment, such as automated test equipment (ATE) or an automated test system (ATS).

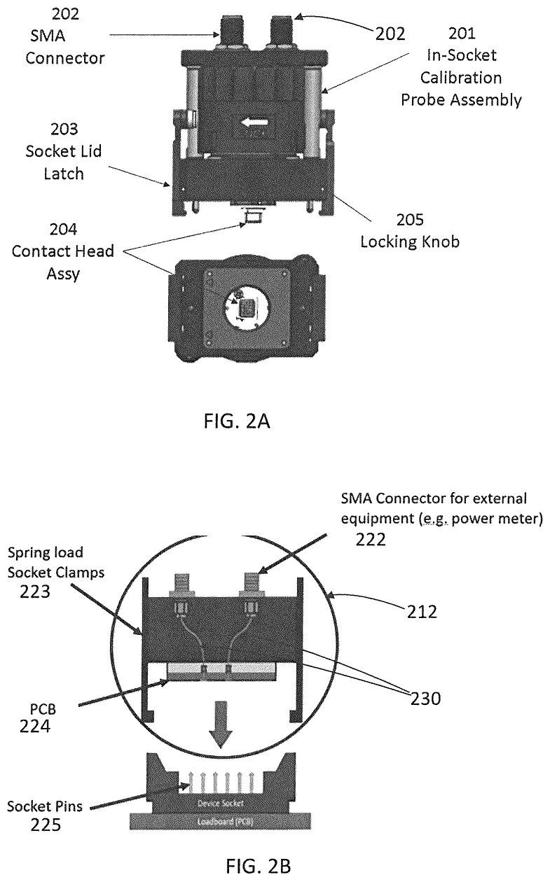

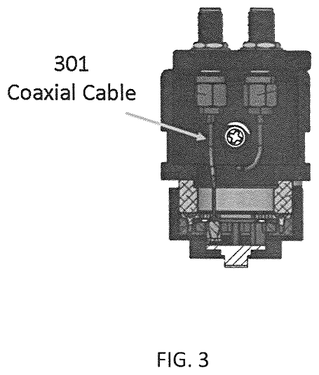

FIG. 2A illustrates an in-socket calibration probe assembly, according to one or more aspects of the various embodiments of the present invention. As discussed above, the in-socket calibration probe assembly 201 is a mechanical fixture that is designed to attach to a device socket to allow for more accurate measurements of the actual RF power signal being delivered to a socket pin (and to the DUT vis-n-vis the socket pin). In some embodiments, the calibration probe assembly 201 can be mounted directly into a socket, thereby, enabling precise electrical connectivity with device socket pins. Upon installation, RF signals are seamlessly transmitted from the printed circuit board (PCB) solder balls on the contact head assembly 204, through a coaxial RF cable (illustrated in FIGS. 2B and 3) to an SMA connector 202. It should be noted that an SMA (SubMiniature version A) connector is a type of coaxial RF connector used for connecting RF cables to printed circuit boards (PCBs). SMA connectors are designed to operate at frequencies from DC (0 Hz) up to 18 GHz, making them suitable for a wide range of radio frequency applications including telecommunications, networking, and test equipment.

A key feature of the in-socket calibration probe assembly 201 is the locking knob 205, which exerts a carefully calibrated force onto the device socket pins (e.g., the device socket pins 103 as shown in FIG. 1) to guarantee secure electrical contact. In some implementations, an advanced torque-controlled variant of the in-socket calibration probe assembly 201 further refines this process. In the advanced torque-controlled variant, the locking knob 205 not only ensures a secure connection but does so with precision and control to ensure highly repeatable measurements. Accordingly, this meticulous application of force enables highly consistent and repeatable measurements, enhancing the reliability and accuracy of RF signal testing in automated test equipment environments.

FIG. 2B illustrates another implementation of the in-socket calibration probe assembly, according to one or more aspects of the various embodiments of the present invention. FIG. 2B illustrates an in-socket calibration probe assembly 212 that is a modified version of the calibration probe assembly 201 shown in FIG. 2A. In the implementation of FIG. 2B, spring loaded socket clamps 223 are used to actuate the probe assembly 212 so that the solder balls on the PCB 224 of the calibration can make secure electrical contact with the socket pins 225. Note that the PCB 224 can be associated with the contact head assembly as discussed in connection with FIG. 2A. Also, as discussed in connection with FIG. 2A, RF signals are transmitted from the solder balls on the PCB 224 (associated with the contact head assembly), through one or more coaxial RF cables 230 to an SMA connector 222. Note that while only two cables 230 are shown in FIG. 2B, there can be fewer than or more than two cables. The number of coaxial cables corresponds to the number of socket pins 225 that need to be probed for calibration purposes.

FIG. 3 illustrates a cross-section of the in-socket calibration probe assembly, according to one or more aspects of the various embodiments of the present invention. As shown in FIG. 3, a coaxial cable 301 transmits the RF signal from a solder ball on the printed circuit board (PCB) associated with the contact head assembly (e.g., contact head assembly 204 shown in FIG. 2A) to an SMA connector.

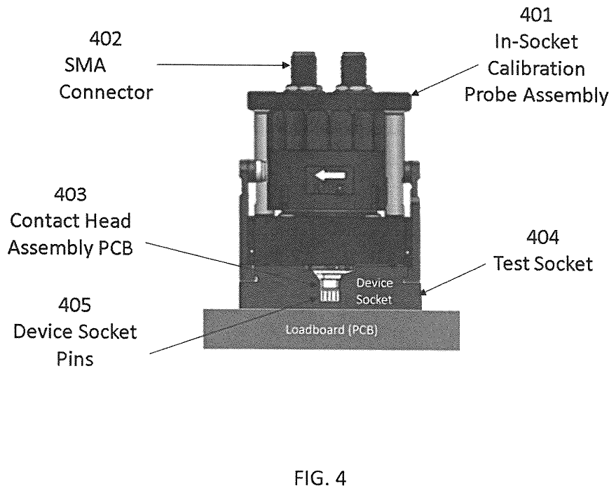

FIG. 4 illustrates the in-socket calibration probe assembly shown in FIG. 2A mounted on a device test socket, according to one or more aspects of the various embodiments of the present invention. As shown in FIG. 4, the in-socket calibration probe assembly 401 is mounted into the test socket 404, which enables electrical connectivity with the device socket pins 405. As discussed above, the solder balls for the contact assembly PCB 403 will make contact with the device socket pins 405 and transfer the signal desired up to the SMA connector 402 via the coaxial cable (e.g., coaxial cable 301 in FIG. 3).

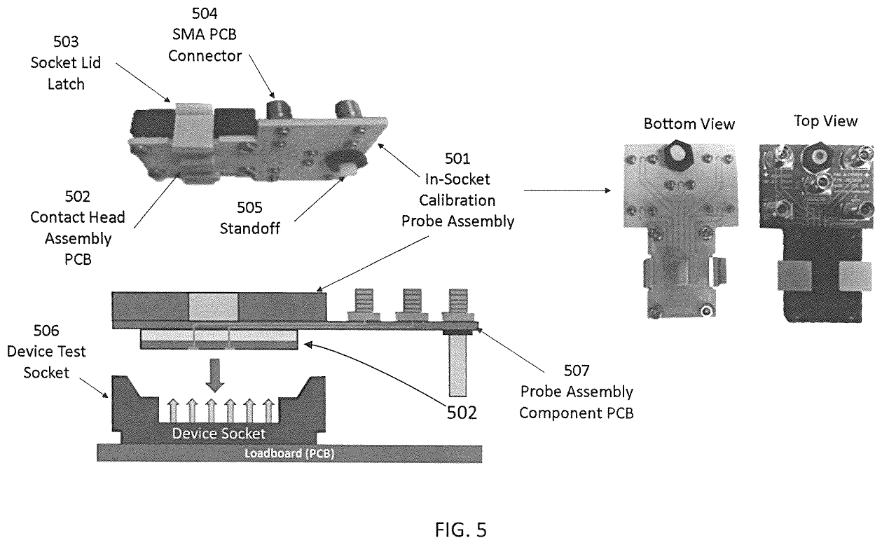

FIG. 5 illustrates another implementation of the in-socket calibration probe assembly, according to one or more aspects of the various embodiments of the present invention. The embodiment shown in FIG. 5 comprises a simpler form factor than the embodiment illustrated in FIG. 2A. For example, the probe assembly 501 in the embodiment shown in FIG. 5 does not incorporate a locking knob and torque adjustment capability. The probe assembly 501 clamps into the device test socket 506 using the socket lid latch 503, which allows the solder balls on the contact head assembly PCB 502 to come into contact with the pins on the device test socket 506. The embodiment shown in FIG. 5 has 5 SMA PCB connectors 504 to allow multiple RF signals associated with device pins on the device test socket 506 to be measured. As mentioned earlier, the number of connectors and corresponding coaxial cables can vary depending on the number of RF signals the test engineer wants to calibrate or measure. In some implementations, the SMA PCB connectors 504 are electrically connected via traces on the probe assembly component PCB 507 and connect down to the device pins via the contact head assembly PCB 502.

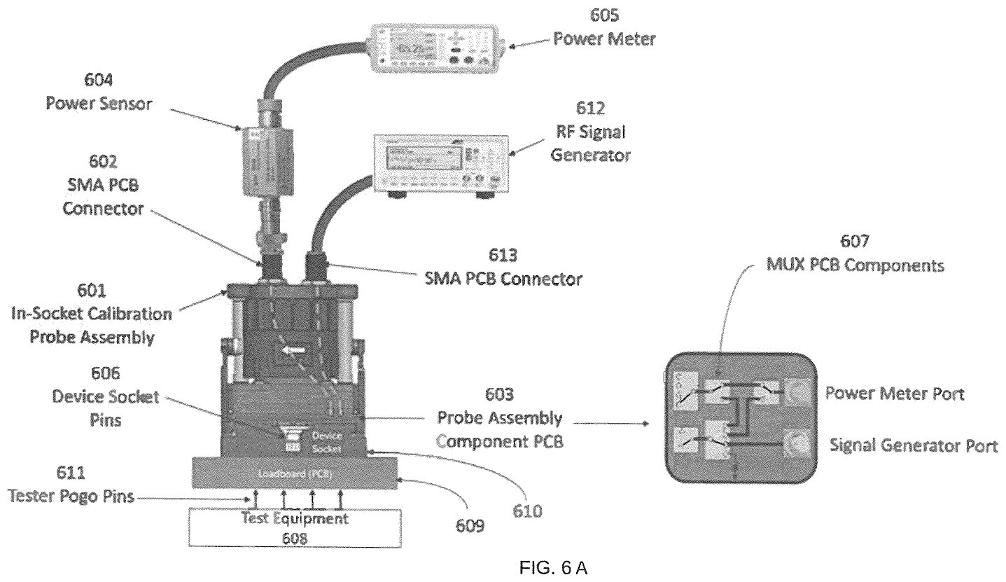

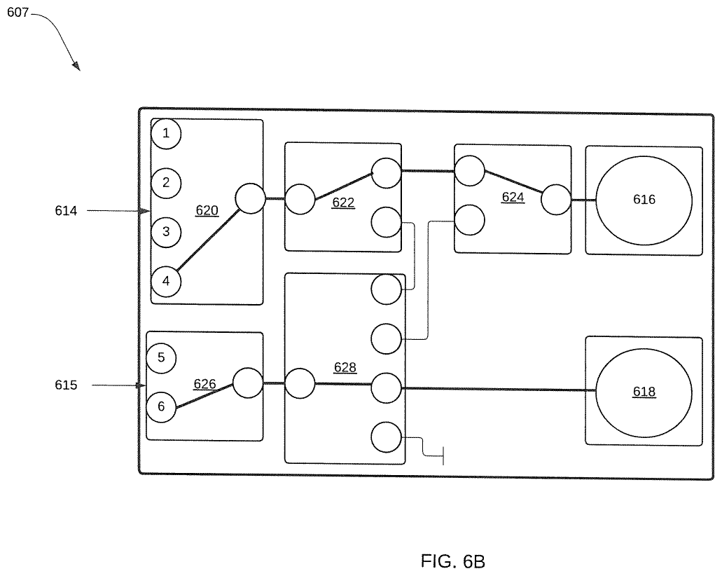

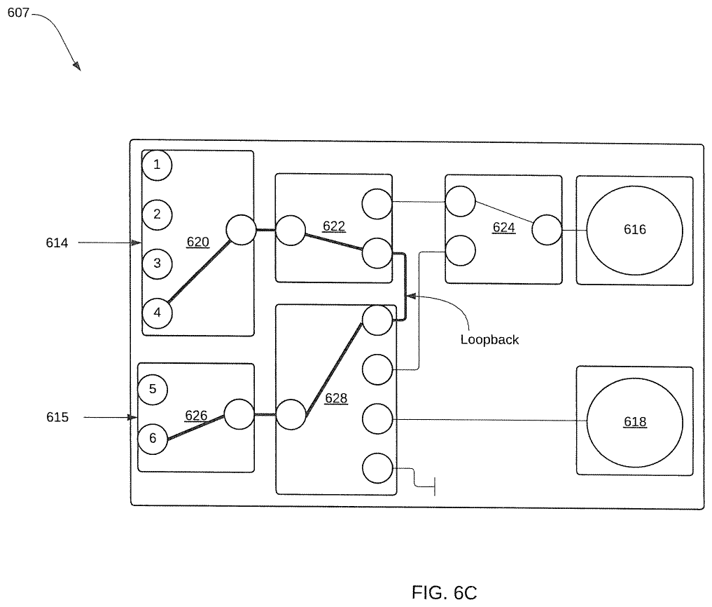

FIG. 6A illustrates a diagram to describe the manner in which socket pins can be calibrated, according to one or more aspects of the various embodiments of the present invention. FIG. 6A illustrates a power sensor 604, a power meter 605, and an RF signal generator 612, which together can be used to stimulate an RF signal or measure the actual RF power being delivered by test equipment 608 to one or more specific device socket pins 606. Test equipment 608 can include an ATE or ATS, for example. The RF power is delivered by the test equipment 608, in some embodiments, through one or more tester pogo pins 611. Note that the function of the power sensor 604 and RF signal generator 612 can depend on one of many things, including the frequency and the application. Accordingly, the in-socket calibration probe assembly 601 enables a test engineer to measure the actual RF power that is delivered to corresponding pads or pins on a DUT when the DUT is placed in the socket 610 and is in operation. In other words, by calibrating the actual power the device socket pin 606 receives, a test engineer is advantageously able to determine the actual power seen on the corresponding pads or pins of a DUT during regular operation. For RF testing, the SMA connectors 602 and 613 located on the in-socket calibration probe assembly 601 are utilized to connect to external equipment such as a power meter 605 or RF signal generator 612. Moreover, as described in more detail below with respect to FIG. 6C, in-socket calibration probe assembly 601 can provide a loopback path to route a signal from one pin of a DUT back to another pin of the same DUT. A signal can be stimulated and measured at the pins to characterize and de-embed the signal path, for example.

In typical implementations, in order to perform the above-mentioned calibration, the test equipment 608 stimulates the appropriate signals. The signals propagate via the loadboard 609 to the device socket pins 606. As mentioned above, typical tester systems do not calibrate or characterize the signal path through the loadboard 609 to the device socket pins 606. The provided socket sp2 files, which attempt to model signal loss through a socket (provided by socket vendors) are not correct or accurate or detailed enough to determine the precise RF power being delivered to the socket pins 606. Accordingly, test engineers often face the challenge of not knowing precisely the actual RF power that is being transmitted to each DUT pin that is placed inside the device socket 610. This uncertainty is due to the losses associated with the loadboard 609 PCB trace and the socket 610. According to some embodiments, RF signal generator 612 is coupled or routed to one or more socket pins to simulate a device signal in order for the test equipment to measure a signal path performance, insertion loss, or test equipment measurement accuracy.

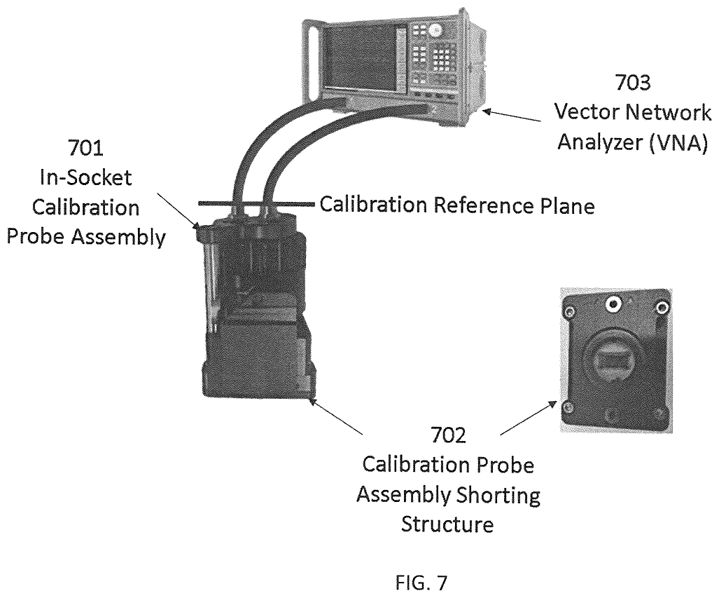

The coaxial cables within the in-socket calibration probe assembly 601 communicate the RF signals from the socket pins 606 to the power sensor 604 and the power meter 605. The power meter 605 is able to then accurately determine the power that is delivered to the one or more device socket pins 606 after performing the process associated with de-embedding for RF insertion loss, as discussed below in connection with FIG. 7. According to some embodiments of the present invention, rather than coupling an RF signal generator 612 to SMA PCB connector 613, another power sensor 604 can be coupled to SMA PCB connector 613, and the two pins can be measured concurrently for faster bench testing.

In many cases, several DUT pins need to be calibrated and measured. Accordingly, corresponding SMA connectors are needed on the calibration probe assembly 601 for each of the signals. As was shown in FIG. 5, in one embodiment, additional SMA connectors can be added to the in-socket calibration probe assembly 601 but in some cases this might not be feasible or desirable due to the number of signals to be tested and the extra space required by the connectors. To address this issue, certain multiplexing/switching components 607 can be added to the probe assembly component PCB 603 also shown in FIG. 6A. In this implementation, multiple switches can be placed on the PCB 603 to route multiple DUT signals (6 DUT signals in this example) to SMA connector 602 and SMA connector 613. It should be noted that when additional components are added to the probe assembly component PCB 603, the power for the switches on the PCB 603 and other required control signals can be supplied directly from the device socket pins 606 that would otherwise normally supply the DUT with similar functionality when the DUT is inserted into the socket instead of the calibration probe assembly 601. The operation of the switches of MUX PCB 607 can be controlled automatically by test equipment 608 to couple components as desired.

FIG. 6B illustrates an exemplary switch PCB 607 having connections to 6 pins (for instance) of a device socket and 2 SMA PCB connectors 616 and 618 (for instance) for coupling DUT signals to external bench equipment according to embodiments of the present invention. In the example of FIG. 6B, 4 pins 614 can be selectively routed to SMA PCB 616 or 618 via switches 620, 622, and 624, and 2 pins 615 can be selectively routed to SMA PCB 616 or 618 via switches 626, 628, and 624. In this way, external bench equipment can be coupled to the SMA PCB connectors 616 and 618 and signals can be routed to the selected DUT pin(s) for testing. Specifically, FIG. 6B shows pin #4 coupled to power meter port 616, and pin #6 coupled to signal generator port 618 via the switches of switch PCB 607. Moreover, as depicted in FIG. 6C discussed below, switches 620, 622, 626, and 628 can be advantageously configured to a loopback path between pins 614 to pins 615, according to embodiments.

FIG. 6C illustrates exemplary switch (MUX) PCB 607 having internal switches configured to provide a loopback path between socket pins according to embodiments of the present invention. The loopback configuration is especially useful, for example, for testing/characterizing DUTs having multiple antennas and/or self-testing components (e.g., loopback components). Specifically, the DUT can generate a signal (e.g., a signal transmitted by a first antenna) and can also receive the signal (e.g., using a second antenna) during testing or characterization. To simulate this functionality, a signal can be stimulated at one pin of the DUT and measured by bench equipment coupled to another pin of the DUT. The received signal can be measured/analyzed in order to test the device or characterize pathways/components of the device. In the example of FIG. 6C, an input signal received at pin #4 is routed (looped back) to pin #6, and both pins #4 and pin #6 are coupled to a DUT disposed on loadboard 609. Importantly, different pins of the DUT can be tested in this way by reconfiguring switches 620, 622, 626, and 628 without having to manually change any connectors, cables, etc.

FIG. 7 illustrates the manner in which the in-socket calibration probe assembly is de-embedded for RF insertion loss, according to one or more aspects of the various embodiments of the present invention. In some embodiments, in order to improve RF power accuracy measurements, the RF signal path(s) associated with the in-socket calibration probe assembly 701 is de-embedded for the associated respective RF insertion losses. Each signal path has an associated RF insertion loss that needs to be taken into account when calibrating a socket pin to determine the actual power being delivered to the pin. In order to properly de-embed the losses, a calibration probe assembly shorting structure 702 is used to mount to the bottom of in-socket calibration probe assembly 701, as shown in FIG. 7. This shorting structure 702 allows for the measurement of accurate RF de-embedding loss values using an external standard 2-port vector network analyzer 703.

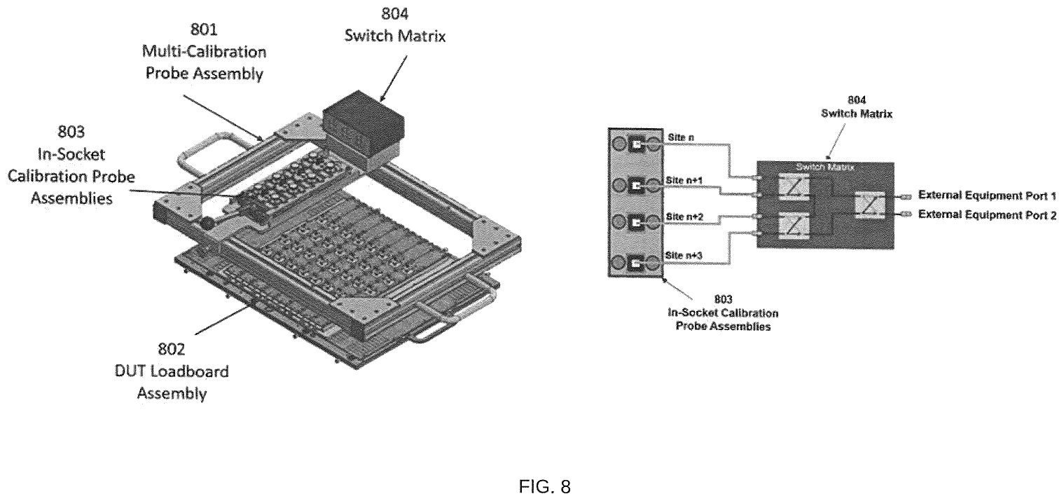

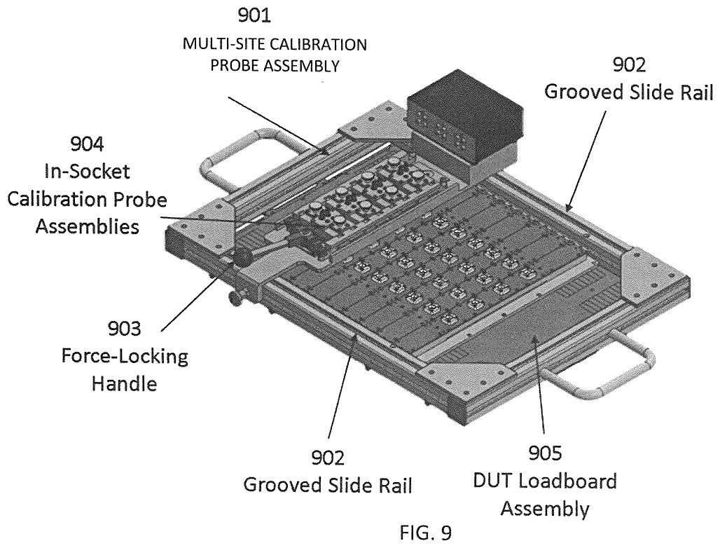

FIG. 8 illustrates a multi-site calibration probe assembly 801, according to one or more aspects of the various embodiments of the present invention. As illustrated in FIG. 8, a multi-site calibration probe assembly 801 can be used to calibrate pins on several sockets on a loadboard assembly 802 simultaneously. With this calibration methodology, multiple sockets (four in this example, but more or less can be included) can be simultaneously contacted for higher calibration throughput. Further, the assembly 801 of FIG. 8 eliminates the hand-clamping of a single in-socket calibration probe assembly (e.g. probe assembly 601 of FIG. 6A).

In some embodiments, a switch matrix 804 can also be used for routing multiple sites to multiple pieces of external equipment without a test engineer or technician having to remove and re-attach cables each time. In this example, the switch matrix can route a single or many signals from any of 4 sites to multiple external pieces of equipment and can also provide a loopback path from one test site to another site. For example, the switches of switch matrix 804 can be configured to route a signal generated by test site n as input to test site n+1. In this way, a signal generated at one socket of DUT loadboard assembly 802 can be routed to another socket as input thereto. The configuration of FIG. 8 results in greater flexibility in measuring and stimulating signals across multiple sites simultaneously. This also results higher accuracy measurements and faster overall calibration time as multiple external instruments can be connected without having to connect and disconnect connections for each site.

FIG. 9 illustrates the manner in which the multi-site calibration probe assembly of FIG. 8 is used to perform calibration, according to one or more aspects of the various embodiments. As illustrated in FIG. 9, the multi-site calibration probe assembly 901 is placed on the DUT loadboard assembly 905. Once the force-locking handle 903 is applied to drop the in-socket calibration probe assemblies 904 into each of the device test sockets, the calibration can be performed. After calibration has been performed, the in-socket calibration probe assemblies 904 can be lifted using the force-locking handle 903, then easily moved to the next set of sockets via the grooved slide rails 902. This process is repeated until all the sockets have been calibrated.

Note that by utilizing this multi-calibration probe assembly methodology illustrated in FIG. 9, the X-Y and Z positioning of the in-socket contact head assembly (e.g., contact head assembly 403) connection with each of the sockets is better controlled as a result of the X-Y staging. This improves repeatability as compared with the operator dependent positioning of a single site since all four sockets are connected via the same mechanism. Furthermore, this process is repeatable across all sites. Additional repeatability can be obtained when this process is automated via motors.

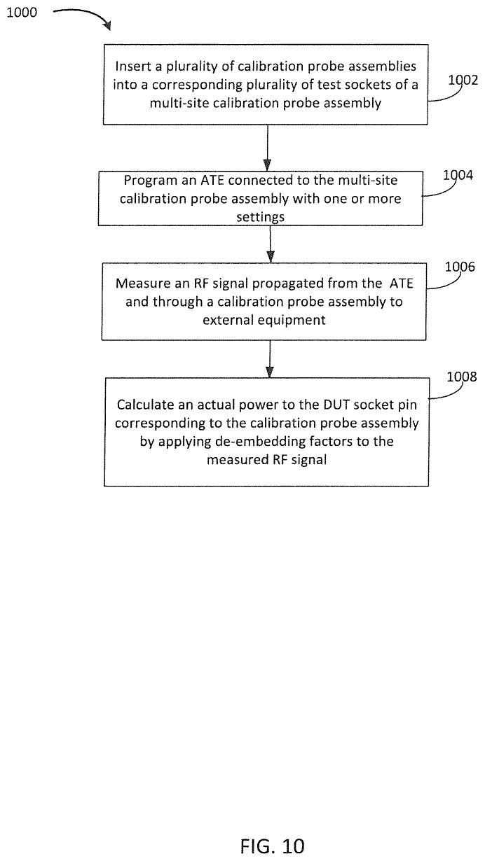

FIG. 10 illustrates a flow diagram of method steps for calibrating RF power signals to a device pin, according to one or more aspects of the various embodiments.

As shown, a method 1000 begins at step 1002, where a plurality of in-socket calibration probe assemblies (e.g., socket probe assembly 201) are inserted into a respective plurality of test sockets (e.g. test socket 404) of a multi-site calibration probe assembly, wherein each of the in-socket calibration probe assemblies is operable to calibrate a power delivered to the socket pins (e.g., device socket pins 405) of a corresponding test socket.

At step 1004, test equipment (e.g., test equipment 608) connected to the plurality of test sockets (and vis-à-vis the test sockets, to the calibration probe assemblies) via a loadboard assembly (e.g. loadboard assembly 802) is programmed with one or more settings. Typically, the settings control the manner in which the test equipment will stimulate one or more signals associated with the device socket pins of the test sockets. The settings can include switch configuration settings used to control switches for coupling different components to enable an RF signal to propagate between the components for testing or characterization purposes.

According to some embodiments, step 1004 includes programming the loadboard assembly with settings used to configure one or more switches to provide a loopback path where an RF signal propagates from one pin of a device or socket to another pin of the same device or socket. According to other embodiments, the loopback path can be used to propagate an RF signal from a pin of one device or socket to a pin of a different device or socket disposed on the same DUT loadboard assembly.

At step 1006, an RF signal is propagated from the test equipment (e.g., tester pogo pins 611 connected to the loadboard assembly 802) and through a calibration probe assembly (e.g., calibration probe assembly 601) of the plurality of calibration probe assemblies (e.g., multi-site calibration probe assembly 803) to external equipment, such as a power sensor (e.g., power sensor 604) and a power meter (e.g., power meter 605). The RF signal is propagated via one or more coaxial cables (e.g., cable 301) that are part of each of the in-socket calibration probe assemblies. S

Importantly, step 1006 can include configuring or controlling one or more switches operable to selectively couple the components for propagating the RF signals (e.g., switches of a loadboard, probe assembly PCB, MUX PCB, etc.). According to some embodiments, the one or more switches are controlled to provide a loopback path between pins of the same device or socket, or between pins of different devices or sockets disposed on the same DUT loadboard assembly via a multi-calibration probe assembly.

At step 1008, an actual power to the socket pin for each test socket is computed by applying de-embedding factors to the measured RF signal. As discussed in connection with FIG. 7, de-embedding factors are measured using a calibration probe assembly shorting structure (e.g., shorting structure 702) mounted to the bottom of in-socket calibration probe assembly. This shorting structure allows for the measurement of accurate RF de-embedding loss values using an external standard 2-port vector network analyzer (e.g., analyzer 703).

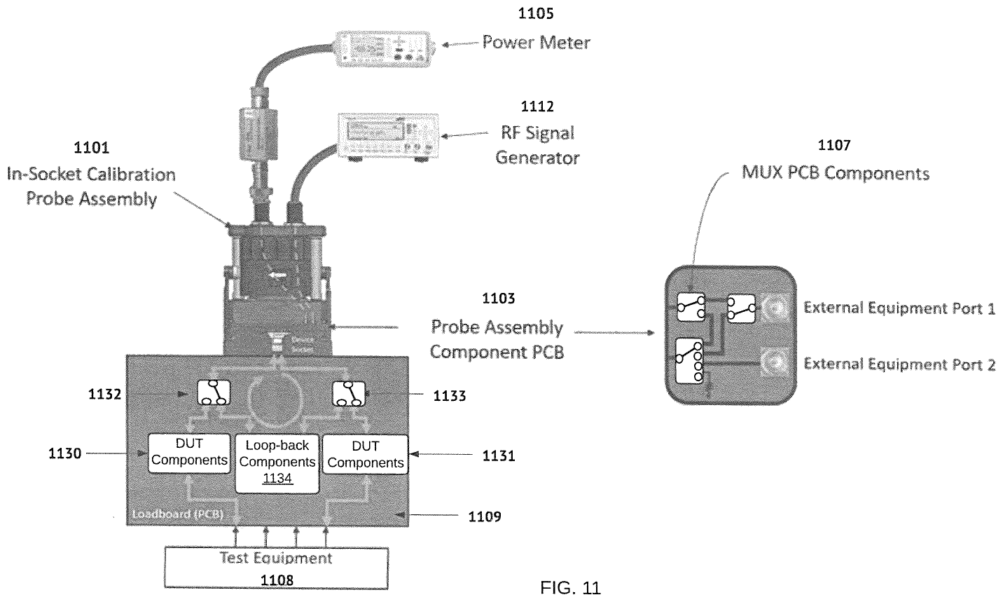

FIG. 11 illustrates another exemplary socket calibration probe assembly 1101 that can provide additional calibration capability using the probe assembly component PCB 1103 according to embodiments of the present invention. This embodiment is especially useful for testing or characterizing a DUT via a loopback path back to the DUT. In the example of FIG. 11, loadboard 1109 provides a loopback path 1134 so that the DUT can both stimulate a signal on one pin and then measure that signal on another pin of the DUT. To address this requirement, both a power meter 1105 and an RF signal generator 1112 can be utilized with the MUX PCB components 1107 to mimic a DUT sending and receiving a signal in loopback mode to itself. After de-embedding the loss of the in-socket calibration probe assembly 1101, the actual performance and loss of the loadboard external loopback path with components can be advantageously accurately measured from one DUT pin to the other DUT pin.

As illustrated in FIG. 11, loadboard 1109 includes components 1130 and 1131 which can be tested via test equipment 1108 or bench instruments 1105, 1112 selectively using MUX PCB 1107 as described above. Moreover, in this example, loadboard 1109 includes DUT loopback components 1134 that can be tested by stimulating a signal at one pin of the DUT and measuring the signal at another pin of the DUT. The signal is routed between the DUT pins via a loopback pathway 1134 provided by MUX PCB components 1107 and loadboard switches 1132, 1133. In this way, a loopback path can be advantageously provided for testing the DUT (e.g., testing multiple antennas of the DUT or other self-testing functionality) without having to manually change cables, devices, equipment, connectors, etc. It should be noted that loadboard switches 1132, 1133 can each toggle between DUT components 1130, 1131 and loopback components 1134 depending on the type of testing to be performed. The operation of switches 1132, 1133 and switches of MUX PCB 1107 can be controlled automatically by test equipment 1108.

In sum, the disclosed embodiments introduce an in-socket calibration probe assembly, designed for seamless integration directly into a device socket. The calibration probe assembly facilitates the direct probing of one or more socket pins, enabling the precise measurement of the actual radio frequency (RF) power being delivered to a device under test (DUT) positioned within the socket utilizing high precision instrumentation. This approach significantly enhances the accuracy of power measurement, as will be elaborated upon further. Test equipment (e.g., an ATE) stimulates one of more device socket pins with an RF signal. The RF signal propagates through one or more coaxial cables within the in-socket calibration probe assembly and is measured by external equipment (e.g., power sensor and a power meter) connected via SMA connectors to the calibration probe assembly. The actual power supplied to the socket pins can then be determined by applying de-embedding factors to the RF signal measured by the power meter. Additionally, a plurality of calibration probe assemblies can be used in a multi-site calibration probe assembly to perform multiple calibrations simultaneously.

At least one technical advantage of the disclosed techniques is the capability to accurately ascertain the actual power supplied to one or more socket pins, and consequently, to the DUT connected via these pins, during device testing performed by test equipment (e.g., an ATE) or bench testing. This precise measurement of power delivery to the DUT is vital for ensuring the integrity and reliability of the testing process, offering a significant improvement over traditional methods that may not provide sufficient accuracy due to losses in the loadboard PCB trace and socket. By directly measuring at the point of contact with the DUT, this method effectively mitigates potential inaccuracies, leading to more reliable and consistent test outcomes. Additionally, a plurality of calibration probe assemblies can be used as part of a multi-site calibration probe assembly system to perform multiple calibrations simultaneously in an automated fashion, which enhances the speed and efficiency with which the calibrations can be performed.

1. In some embodiments, a method comprises inserting a calibration probe assembly into a test socket, programming a test equipment communicatively coupled to the test socket to control operation of a first switch to selectively couple a first pin of the test socket to a first equipment port of the test equipment, and control operation of a second switch to selectively couple a second pin of the test socket to a second equipment port of the test equipment, electrically stimulating the first pin with an RF signal via the first equipment port, measuring the RF signal propagated from the first pin and received at the second pin via the second equipment port, and determining a power value associated with the RF signal.

2. The method of clause 1, wherein determining the power value comprises applying de-embedding factors to the RF signal measured by the measuring.

3. The method of clause 1 or 2, further comprising measuring the de-embedding factors by mounting a calibration probe assembly shorting structure to a bottom of the calibration probe assembly, and measuring the de-embedding factors using a vector network analyzer connected to the calibration probe assembly.

4. The method of any of clauses 1 through 3, wherein the calibration probe assembly comprises one or more coaxial cables, wherein the RF signal is propagated through the calibration probe assembly using at least one cable of the one or more coaxial cables, and wherein the measuring the RF signal comprises using external equipment to measure the RF signal that is propagated through the calibration probe assembly.

5. The method of any of clauses 1 through 4, wherein the first equipment port comprises a coaxial connector coupled to a power meter.

6. The method of any of clauses 1 through 5, further comprising testing a device under test (DUT) disposed in the test socket according to the power value associated with the RF signal.

7. In some embodiments, a method comprises inserting a plurality of calibration probe assemblies into a respective plurality of test sockets of a multi-site calibration probe assembly, for a first test socket of the plurality of test sockets programming a test equipment communicatively coupled to the first test socket to selectively couple a first pin of the first test socket to a second pin of the first test socket via a plurality of switches, electrically stimulating the first pin with an RF signal, measuring the RF signal propagated from the first pin to the second pin, and determining a power value associated with the RF signal measured by the measuring.

8. The method of clause 7, wherein determining the power value comprises applying de-embedding factors to the RF signal measured by the measuring.

9. The method of clause 7 or 8, further comprising programming the test equipment to selectively couple the first pin of the first test socket to a first equipment port of the test equipment, and selectively couple the second pin of the first test socket to a second equipment port of the test equipment.

10. The method of any of clauses 7 through 9, wherein the electrically stimulating the first pin with the RF signal is performed via the first equipment port, and wherein the measuring the RF signal propagated from the first pin to the second pin is performed via the second equipment port.

11. The method of any of clauses 7 through 10, wherein the first equipment port is coupled to an RF signal generator, and wherein the second equipment port is coupled to a power meter.

12. The method of any of clauses 7 through 11, wherein the plurality of test sockets are disposed on a loadboard assembly, wherein the plurality of test sockets are operable to receive devices under test (DUTs), and wherein the loadboard assembly comprises a plurality of switches that selectively couple any of the plurality of test sockets to either: components of DUTs disposed in the plurality of sockets; or loopback components of the DUTs, and wherein the DUTs are operable to both generate the RF signal and receive the RF signal via the loopback components.

13. The method of any of clauses 7 through 12, further comprising testing a DUT disposed in the test socket according to the power value.

14. The method of clause 13, wherein the DUT comprises a first component operable to transmit the RF signal at the first pin, and a second component operable to receive the RF signal at the second pin via a loopback path provided by the plurality of switches.

15. In some embodiments, a device comprises a test socket comprising a plurality of pins operable to be coupled to pins of a device under test (DUT), a probe assembly comprising a first equipment port, and a second equipment port, and a plurality of switches operable to selectively couple the plurality of pins of the test socket to one of the first equipment port and the second equipment port, a first bench equipment coupled to the first equipment port and operable to electrically stimulate a first pin of the plurality of pins of the test socket with an RF signal, a second bench equipment coupled to the second equipment port and operable to measure the RF signal propagated from the first pin and received at a second pin of the plurality of pins of the test socket via the second equipment port, and test equipment operable to determine a power value associated with the RF signal.

16. The device of clause 15, wherein the test equipment is further operable to test the DUT according to the power value when the DUT is disposed in the test socket.

17. The device of clause 15 or 16, wherein the first equipment port is coupled to an RF signal generator and the second equipment port is coupled to a power meter.

18 The device of any clause 15 through 17, wherein the plurality of switches are further operable to provide a loopback path.

19. The device of clause 18, wherein the DUT is disposed in the test socket, and wherein the DUT is operable to generate an RF signal on the loopback path.

20. The device of clause 18 or 19, wherein the DUT is further operable to receive the RF signal from the loopback path, wherein the loopback path is operable to route the RF signal from the DUT back to the DUT via the plurality of switches.

Any and all combinations of any of the claim elements recited in any of the claims and/or any elements described in this application, in any fashion, fall within the contemplated scope of the present protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A method comprising:
inserting a calibration probe assembly into a test socket;
programming a test equipment communicatively coupled to the test socket to:
control operation of a first switch to selectively couple a first pin of the test socket to a first equipment port of the test equipment; and
control operation of a second switch to selectively couple a second pin of the test socket to a second equipment port of the test equipment;
electrically stimulating the first pin with an RF signal via the first equipment port;
measuring the RF signal propagated from the first pin and received at the second pin via the second equipment port; and
determining a power value associated with the RF signal.

2. The method of claim 1, wherein determining the power value comprises applying de-embedding factors to the RF signal measured by the measuring.

3. The method of claim 2, further comprising measuring the de-embedding factors by:
mounting a calibration probe assembly shorting structure to a bottom of the calibration probe assembly; and
measuring the de-embedding factors using a vector network analyzer connected to the calibration probe assembly.

4. The method of claim 1, wherein the calibration probe assembly comprises one or more coaxial cables, wherein the RF signal is propagated through the calibration probe assembly using at least one cable of the one or more coaxial cables, and wherein the measuring the RF signal comprises using external equipment to measure the RF signal that is propagated through the calibration probe assembly.

5. The method of claim 1, wherein the first equipment port comprises a coaxial connector coupled to a power meter.

6. The method of claim 1, further comprising testing a device under test (DUT) disposed in the test socket according to the power value associated with the RF signal.

7. A method comprising:
inserting a plurality of calibration probe assemblies into a respective plurality of test sockets of a multi-site calibration probe assembly;
for a first test socket of the plurality of test sockets:
programming a test equipment communicatively coupled to the first test socket to selectively couple a first pin of the first test socket to a second pin of the first test socket via a plurality of switches;
electrically stimulating the first pin with an RF signal;
measuring the RF signal propagated from the first pin to the second pin; and
determining a power value associated with the RF signal measured by the measuring.

8. The method of claim 7, wherein the determining the power value comprises applying de-embedding factors to the RF signal measured by the measuring.

9. The method of claim 7, further comprising programming the test equipment to:
selectively couple the first pin of the first test socket to a first equipment port of the test equipment; and
selectively couple the second pin of the first test socket to a second equipment port of the test equipment.

10. The method of claim 9, wherein the electrically stimulating the first pin with the RF signal is performed via the first equipment port, and wherein the measuring the RF signal propagated from the first pin to the second pin is performed via the second equipment port.

11. The method of claim 10, wherein the first equipment port is coupled to an RF signal generator, and wherein the second equipment port is coupled to a power meter.

12. The method of claim 7, wherein the plurality of test sockets are disposed on a loadboard assembly, wherein the plurality of test sockets are operable to receive devices under test (DUTs), and wherein the loadboard assembly comprises a plurality of switches that selectively couple any of the plurality of test sockets to either: components of DUTs disposed in the plurality of sockets; or loopback components of the DUTs, and wherein the DUTs are operable to both generate the RF signal and receive the RF signal via the loopback components.

13. The method of claim 7, further comprising testing a DUT disposed in the test socket according to the power value.

14. The method of claim 13, wherein the DUT comprises:
a first component operable to transmit the RF signal at the first pin; and
a second component operable to receive the RF signal at the second pin via a loopback path provided by the plurality of switches.

15. A device comprising:
a test socket comprising a plurality of pins operable to be coupled to pins of a device under test (DUT);
a probe assembly comprising:
a first equipment port; and
a second equipment port;
a plurality of switches operable to selectively couple the plurality of pins of the test socket to one of the first equipment port and the second equipment port;
a first bench equipment coupled to the first equipment port and operable to electrically stimulate a first pin of the plurality of pins of the test socket with an RF signal;
a second bench equipment coupled to the second equipment port and operable to measure the RF signal propagated from the first pin and received at a second pin of the plurality of pins of the test socket via the second equipment port; and
test equipment operable to determine a power value associated with the RF signal.

16. The device of claim 15, wherein the test equipment is further operable to test the DUT according to the power value when the DUT is disposed in the test socket.

17. The device of claim 15, wherein the first equipment port is coupled to an RF signal generator and the second equipment port is coupled to a power meter.

18. The device of claim 15, wherein the plurality of switches are further operable to provide a loopback path between a first pin of the plurality of pins of the test socket and a second pin of the plurality of pins of the test socket.

19. The device of claim 18, wherein the DUT is disposed in the test socket, and wherein the DUT is operable to generate an RF signal on the loopback path.

20. The device of claim 19, wherein the DUT is further operable to receive the RF signal from the loopback path, wherein the loopback path is operable to route the RF signal from the DUT back to the DUT via the plurality of switches.
